(19) United States
(12) Patent Application Publication
(10) Pub. No.: US 2009/0161189 A1
(43) Pub. Date: Jun. 25, 2009

(54) METHOD OF MANUFACTURING A STRUCTURE BASED ON ANISOTROPIC ETCHING, AND SILICON SUBSTRATE WITH ETCHING MASK

(75) Inventors: Kaoru Noguchi, Tokyo (JP); Yoshio Hotta, Kamakura-shi (JP); Kazutoshi Torashima, Palo Alto, CA (US); Yutaka Setomoto, Tokyo (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/333,910

(22) Filed: Dec. 12, 2008

(30) Foreign Application Priority Data
Dec. 19, 2007 (JP) 2007-327510

(51) Int. Cl. G02B 26/08; G03F 7/20; G03F 1/00

(52) U.S. Cl. 359/198.1; 430/321; 430/5

(57) ABSTRACT

A method of manufacturing a structure that includes a mask forming step for forming, on a monocrystal silicon substrate, a base etching mask corresponding to a target shape and a correction etching mask having a joint connecting to the base etching mask, and a target shape forming step for forming the target shape by anisotropically etching the silicon substrate, wherein, in the mask forming step, a lowered-strength portion where a mechanical strength is locally decreased is formed at least in a portion of the joint of the correction etching mask.

### FIELD OF THE INVENTION AND RELATED ART

This invention relates to a method of manufacturing a structure based on anisotropic etching and to a silicon substrate with an etching mask. More particularly, the invention concerns a method of manufacturing a monocrystal silicon substrate with an etching mask and a structure (e.g., microstructure), such as an optical deflector, using the monocrystal silicon substrate, and an optical instrument, such as an optical deflector, manufactured by the manufacturing method. The optical deflectors to be manufactured by this manufacturing method can be suitably used in a projection display device for projecting an image by scanning deflection of light or an image forming apparatus, such as a laser beam printer or a digital copying machine employing an electrophotographic process.

Micromechanical members to be produced from a silicon substrate by a semiconductor process can have a processing precision of a micrometer order. Thus, various micro-function devices have been produced based thereon. Particularly, as compared with conventional optical-scanning optical systems using a rotary polygonal mirror, such as a polygon mirror, the optical deflectors based on such micromechanical members have the following advantages: the size of the optical deflector can be made small; the power consumption is quite small; and so on.

An example of a proposal made thus far is an optical deflector manufactured by using anisotropic wet etching, which is one of the semiconductor processes (U.S. Patent Application Publication Nos. 2002/0113675 and 2002/0114053). Furthermore, as a technique for etching a silicon substrate by anisotropic wet etching to obtain a desired target shape (the shape corresponding to a base etching mask), the use of a correction etching mask has been proposed (Japanese Laid-Open Patent Application No. 7-58345).

### SUMMARY OF THE INVENTION

When a target shape is made by using anisotropic wet etching of silicon, there is a possibility that, during the etching process or after the etching process, a correction etching mask, which leads to a base etching mask, may come off or become damaged. If the broken correction etching mask adheres to the target shape that is being formed in an unwanted manner, a certain portion of the final product will have a shape different from the desired target shape. There will not be a problem if such a portion having a different shape does not seriously affect the function of the product. However, if the accuracy in the shape is strictly required in such a portion, this leads to a decreased yield of the products.

The present invention provides a method of manufacturing a structure based on anisotropic etching by which at least one of the inconveniences described above can be prevented or reduced.

In accordance with an aspect of the present invention, there is provided a method of manufacturing a structure, comprising a mask forming step for forming, on a monocrystal silicon substrate, a base etching mask corresponding to a target shape and a correction etching mask having a joint connecting to the base etching mask, and a target shape forming step for forming the target shape by etching the silicon substrate based on anisotropic etching. In the mask forming step, a lowered-strength portion, where a mechanical strength is locally decreased, is formed at least in a portion of the joint of the correction etching mask.

In accordance with another aspect of the present invention, there is provided a method of manufacturing a structure comprising a mask forming step for forming, on a monocrystal silicon substrate, a base etching mask corresponding to a target shape having at least a first structure with a projected corner and a second structure adjoining the first structure with an opening interposed therebetween, and a correction etching mask extending from the projected corner of the etching mask of the first structure and connecting to the etching mask of the second structure, and a target shape forming step for forming the target shape by making anisotropic etching of the silicon substrate having the base etching mask and the correction etching mask. In the mask forming step, a lowered-strength portion where a mechanical strength is locally decreased is formed at least in a portion of a joint where the base etching mask of the first structure connects with the correction etching mask.

In one preferred form of this aspect of the present invention, the correction etching mask has a Y-shape form in which it extends from the projected corner of the etching mask of the first structure in [110] directions and in which respective correction etching masks branched in the [100] directions connect with the etching mask of the second structure.

The target shape forming step may include a step of removing the silicon substrate in a portion where the correction etching mask is formed.

The method may further comprise a disconnecting step for cutting the correction etching mask at the joint in which the lowered-strength portion is formed.

The lowered-strength portion may be provided by at least one of (i) one or more through-holes, (ii) one or more slits and (iii) one or more thin-thickness portions.

In the disconnecting step, the correction etching mask may be cut at the joint where the lowered-strength portion is formed, the cutting being made based on at least one of (i) oscillating the silicon substrate in an anisotropic etching solution for the anisotropic etching, (ii) revolving the silicon substrate in an anisotropic etching solution for the anisotropic etching, (iii) applying a water shower to the silicon substrate during water rinsing of the silicon substrate, (iv) blowing air against the silicon substrate during the drying of the silicon substrate, and (v) applying an ultrasonic vibration to the silicon substrate in an anisotropic etching solution for the anisotropic etching or during water rinsing of the silicon substrate.

In accordance with a further aspect of the present invention, there is provided a silicon substrate with an etching mask, comprising a monocrystal silicon substrate, a base etching mask corresponding to a target shape and formed on the monocrystal silicon substrate, a correction etching mask having a joint connecting to the base etching mask and formed on the monocrystal silicon substrate, a lowered-strength portion having a locally decreased mechanical strength and formed at least in a portion of the joint of the correction etching mask.

In accordance with a yet further aspect of the present invention, there is provided an oscillator device, comprising a supporting member, a movable member being movably supported relative to the supporting member; a resilient supporting member for resiliently connecting the movable member to the supporting member for an oscillating motion around an oscillation axis, and a driving member for driving the movable member. The oscillator device is manufactured in accordance with the manufacturing method as recited above.

In accordance with a still further aspect of the present invention, there is provided an optical deflector, comprising an oscillator device as recited above and an optical deflecting element provided on the movable member.

In accordance with another aspect of the present invention, there is provided an optical instrument, comprising an optical deflector as recited above. This optical deflector is configured to deflect a light beam from a light source, such that at least a portion of the light beam is incident on an object to be irradiated thereby.

Since the present invention uses a correction etching mask having a lowered-strength portion as described above, the possibility of peeling off or damaging the correction etching mask, which leads to a base etching mask, is reduced. Hence, the possibility that the final shape of the structure formed by the etching differs from a desired target shape can be reduced, and therefore, the deficient product ratio of the structure can be reduced.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1A is a top plan view for explaining an etching mask according to an embodiment of the present invention and, specifically, to a first working example of the present invention.

FIG. 1B is a fragmentary and enlarged view of a portion of FIG. 1A.

FIG. 2A is a top plan view of an oscillator device or an optical deflector according to the first working example, manufactured in accordance with the structure manufacturing method of the present invention.

FIG. 2B is a section view of FIG. 2A.

FIG. 3A is a top plan view for explaining a portion of a correction etching mask in an embodiment of the present invention and, specifically, according to the first working example of the present invention.

FIG. 3B is a top plan view for explaining an initial-stage etching process in a portion of the correction etching mask of FIG. 3A.

FIG. 3C is a top plan view for explaining a middle-stage etching process in a portion of the correction etching mask in an embodiment of the present invention and, specifically, according to the first working example of the present invention.

FIG. 3D is a top plan view for explaining a final-stage etching process in a portion of the correction etching mask of FIG. 3C.

FIG. 4A is a top plan view for explaining an etching mask in an embodiment of the present invention.

FIG. 4B is an enlarged view of a portion of the etching mask of FIG. 4A.

FIG. 5A is a top plan view for explaining a portion of a correction etching mask in the embodiment of the present invention shown in FIG. 4A.

FIG. 5B is a top plan view for explaining an initial-stage etching process in a portion of the correction etching mask of FIG. 5A.

FIG. 5C is a top plan view for explaining a middle-stage etching process in a portion of the correction etching mask in the embodiment of the present invention shown in FIG. 4A.

FIG. 5D is a top plan view for explaining a final-stage etching process in a portion of the correction etching mask of FIG. 5C.

FIG. 6A is a top plan view for explaining an etching mask in an embodiment of the present invention.

FIG. 6B is an enlarged view of a portion of the etching mask of FIG. 6A.

FIG. 7A is a top plan view for explaining a portion of a correction etching mask in the embodiment of the present invention shown in FIG. 6A.

FIG. 7B is a top plan view for explaining an initial-stage etching process in a portion of the correction etching mask of FIG. 7A.

FIG. 7C is a top plan view for explaining a middle-stage etching process in a portion of the correction etching mask in the embodiment of the present invention shown in FIG. 6A.

FIG. 7D is a top plan view for explaining a final-stage etching process in a portion of the correction etching mask of FIG. 7C.

FIG. 8 is a top plan view for explaining an etching mask in an embodiment of the present invention and, specifically, according to a second working example of the present invention.

FIG. 9A is a top plan view for explaining a portion of a correction etching mask in an embodiment of the present invention and, specifically, according to the second working example of the present invention.

FIG. 9B is a top plan view for explaining an initial-stage etching process in a portion of the correction etching mask of FIG. 9A.

FIG. 9C is a top plan view for explaining a middle-stage etching process in a portion of the correction etching mask in an embodiment of the present invention and, specifically, according to the second working example of the present invention.

FIG. 9D is a top plan view for explaining a final-stage etching process in a portion of the correction etching mask of FIG. 9C.

FIGS. 10A-10C are A1-A2 sectional views of FIG. 8, respectively, for explaining the effect of the correction etching mask in an embodiment of the present invention and according to the second working example of the present invention.

FIG. 11 is a top plan view for explaining an etching mask in an embodiment of the present invention.

FIG. 12A is a top plan view for explaining a portion of a correction etching mask in the embodiment of the present invention shown in FIG. 11.

FIG. 12B is a top plan view for explaining an initial-stage etching process in a portion of the correction etching mask of FIG. 12A.

FIG. 12C is a top plan view for explaining a middle-stage etching process in a portion of the correction etching mask in the embodiment of the present invention shown in FIG. 11.

FIG. 12D is a top plan view for explaining a final-stage etching process in a portion of the correction etching mask of FIG. 12C.

FIG. 13 is a top plan view for explaining an etching mask in an embodiment of the present invention.

FIG. 14A is a top plan view for explaining a portion of a correction etching mask in the embodiment of the present invention shown in FIG. 13.

FIG. 14B is a top plan view for explaining an initial-stage etching process in a portion of the correction etching mask of FIG. 14A.

FIG. 14C is a top plan view for explaining a middle-stage etching process in a portion of the correction etching mask in the embodiment of the present invention shown in FIG. 13.

FIG. 14D is a top plan view for explaining a final-stage etching process in a portion of the correction etching mask of FIG. 14C.

FIG. 15 is a perspective view for explaining an image forming apparatus according to the present invention.

### DESCRIPTION OF THE PREFERRED EMBODIMENTS

Preferred embodiments of the present invention will now be described with reference to the attached drawings.

In the method of manufacturing a structure based on anisotropic etching according to the present invention or in the process of forming an etching mask of the present invention, the following requirements have to be satisfied. First, a base etching mask corresponding to the target shape and a correction etching mask having a joint connecting to the base etching mask have to be formed on a monocrystal silicon substrate (mask forming step). In the correction etching mask, a lowered-strength portion in which the mechanical strength is locally decreased is formed at least in a portion of the joint. Then, the monocrystal silicon substrate having the aforementioned base etching mask and correction etching mask is etched by anisotropic etching, whereby the target shape is formed (target shape forming step). During this process, the portion of the monocrystal silicon substrate in which the correction etching mask is formed is removed by the etching.

Typically, the lowered-strength portion is formed at the joint of the correction etching mask, which connects to a predetermined important portion of the base etching mask. The predetermined important portion may be, for example, a portion of the base etching mask, which corresponds to a portion like a movable member described below in which geometrical accuracy is required. In the embodiments of the present invention or in the working examples of the present invention described below, the structure includes a movable member, a supporting member, and a resilient supporting member. However, in the present invention, the structure is not limited thereto. More specifically, although a structure, such as an oscillator device including a portion like a movable member having a projecting corner, is a typical model, the present invention can be applied to any type of structure. For example, the invention can be applied to a microstructure, such as an acceleration sensor or an angular velocity sensor, which can be made using a micromachining technique.

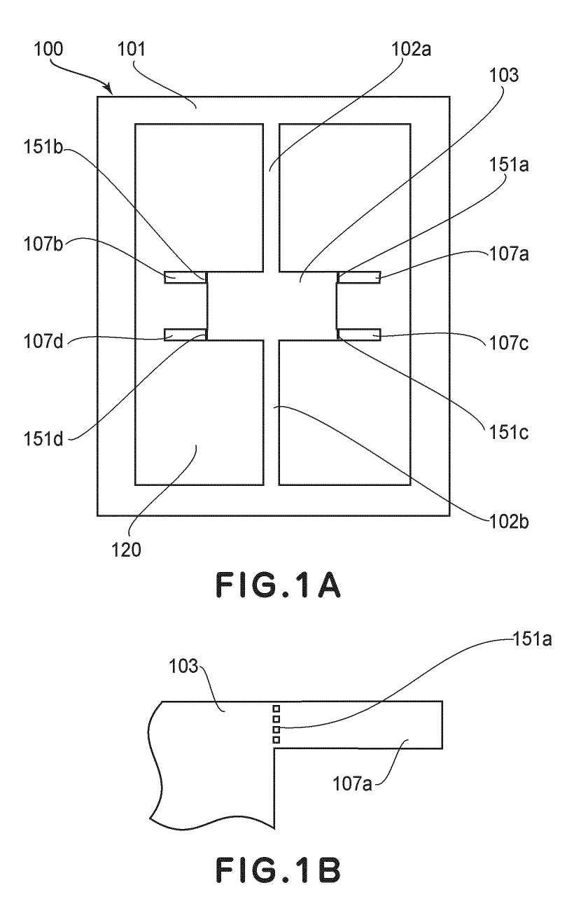

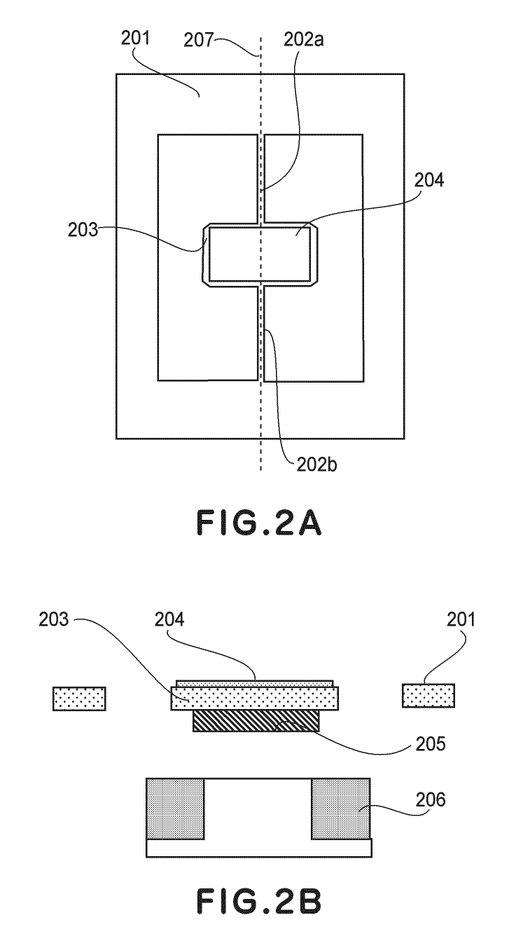

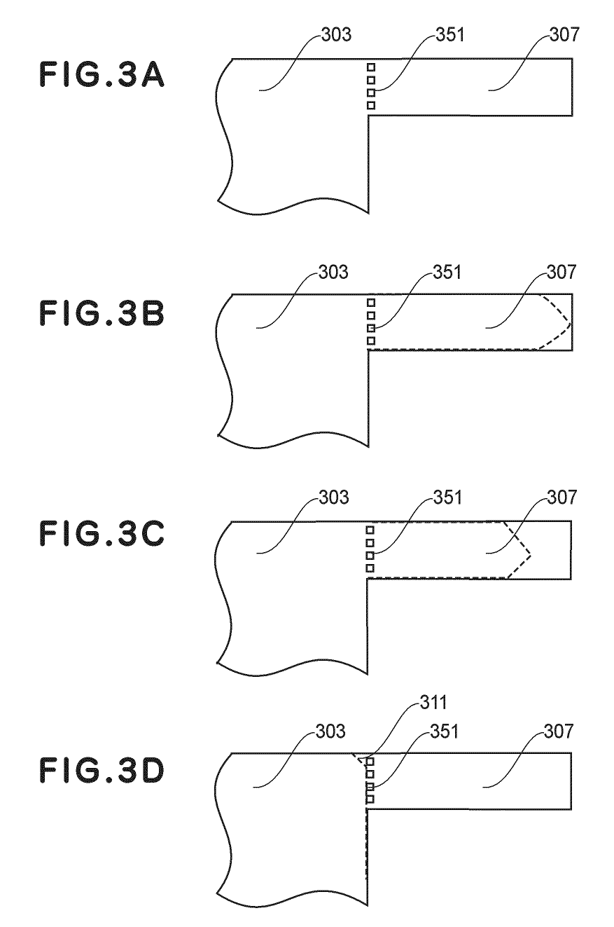

FIG. 1A is a top plan view illustrating an etching mask of a structure, such as a microstructure in one embodiment of the present invention. FIG. 1B is an enlarged view of a portion of the correction etching mask. FIG. 2A is a top plan view illustrating a structure, such as a microstructure to be produced by using anisotropic etching of a monocrystal silicon substrate. FIG. 2B is a sectional view thereof. FIG. 3A and FIG. 3B are enlarged top plan views of a portion of the correction etching mask in this embodiment of the present invention, and these are diagrams for explaining how a monocrystal silicon substrate underneath the correction etching mask is etched by anisotropic etching.

In the structure manufacturing method in this embodiment of the present invention, the structure, such as shown in FIG. 2A, which is comprised of a supporting member 201, resilient supporting members 202a and 202b, and a movable member 203 oscillating around a torsion axis 207, is the target shape. The resilient supporting members 202a and 202b resiliently couple the movable member 203 to the supporting member 201 for oscillation around the oscillation axis. This structure has a reflection surface 204 and comprises a magnetic material 205 and an electric coil 206, such as shown in FIG. 2B. Thus, it can be used as an optical deflector for deflectively reflecting incident light at the reflection surface 204.

In the manufacturing method of the structure of this embodiment of the present invention, a monocrystal silicon substrate having a (100) surface as a principal surface is etched by anisotropic wet etching using which the target shape is formed. The anisotropic wet etching is an etching process in which such an etchant is used that the etching does not progress with respect to a particular crystal orientation. With this etching process, a structure having a predetermined crystal plane as a reference, namely, a structure defined by such a crystal plane, can be made with a very high finishing precision. Examples of anisotropic etchants are KOH (potassium hydroxide), TMAH (tetramethyl ammonium hydroxide water solution), EDP (ethylenediamine pyrocatechol+water), NaOH (sodium hydroxide), and hydrazine.

When a monocrystal silicon substrate is etched by an anisotropic etching solution, in order to ensure that the silicon substrate is etched exactly in accordance with the target shape, a base etching mask corresponding to the target shape and a correction etching mask for protecting a protruding portion of the target shape are used. Namely, the correction etching mask functions to prevent a protruding portion of the target shape from being etched during the etching process in which the silicon substrate is etched into the target shape. The base etching mask of FIG. 1 includes a supporting member 201, resilient supporting members 202a and 202b, and portions 101, 102a, 102b, and 103 corresponding to the movable member 203, respectively (hereinafter, these mask portions will be referred to also as “supporting member 101”). Furthermore, the correction etching mask includes portions 107a, 107b, 107c, and 107d (hereinafter, these portions may be referred to also as “correction etching mask”). Hence, the correction etching mask 107a, 107b, 107c, and 107d of FIG. 1 prevents the projecting corner of the movable member 203 from being etched until the supporting member 201, resilient supporting members 202a and 202b, and the movable member 203 shown in FIG. 2A are made.

The method of manufacturing a structure in this embodiment of the present invention will be explained. First, a masking material is layered on both sides of the monocrystal silicon substrate 100. The mask material should be such that it is not removed while the silicon substrate is etched by the anisotropic etching solution. The mask material may be, for example, a silicon nitride film or an oxidation silicon film. A mask pattern, such as shown in FIG. 1, can be formed by a photolithographic process and patterning of the masking material. After the mask pattern formation, the silicon substrate 100 is dipped in an anisotropic etching solution using which a silicon penetrated portion 120 is formed such that the final shape as shown in FIG. 2A can be formed.

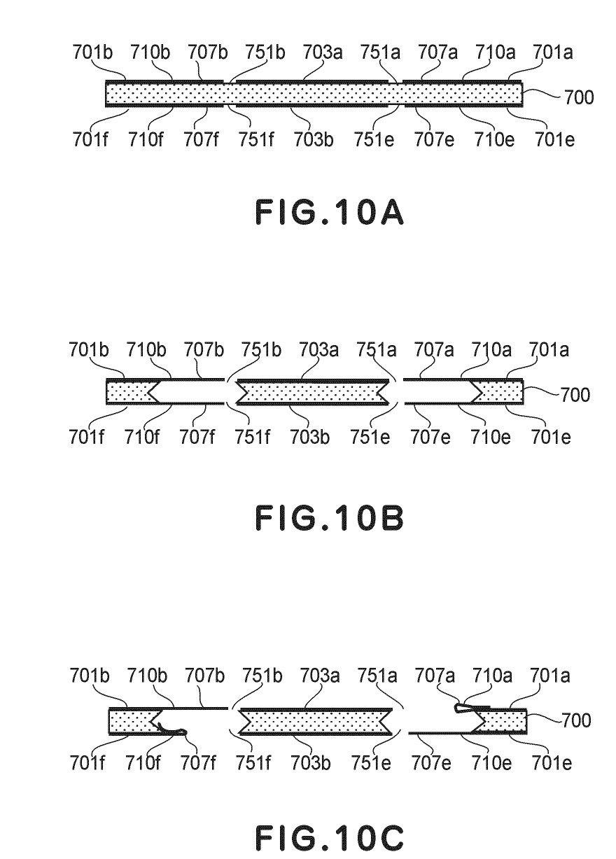

In this process, if a side face of the silicon substrate 100 is exposed to the etching solution, a masking material may be layered on the side face. It should be noted that the mask pattern may be formed on only one side of the monocrystal silicon substrate 100 and the etching may be carried out while the masking material may be formed on the other surfaces. In that occasion, however, the etching action may differ from that shown in FIG. 10. Furthermore, plural structures juxtaposed with each other may be produced from one piece of the silicon substrate. In that case, since these structures are adjoining, the masking material should be layered on the side surface of the silicon substrate.

In the structure manufacturing method in this embodiment of the present invention, the correction etching mask 107a, 107b, 107c, and 107d couples with the movable member 103, which is the base etching mask. There is more than one through-hole 151a, 152b, 153c, and 154d at the joint of the correction etching mask with the movable member 103. Namely, a lowered-strength portion in which the mechanical strength is locally decreased is formed at the joint of the correction etching mask connecting to a predetermined portion of the base etching mask.

The function and effect of the correction etching mask in the structure manufacturing method in this embodiment of the present invention will be explained.

FIGS. 3A-3D are enlarged views, respectively, illustrating the etching process in a portion 107a of the correction etching mask of FIG. 1, wherein the components corresponding to those of FIG. 1 are denoted by numerals in the 300s. As shown in FIG. 3A, a base etching mask 303 of the movable member is formed on the monocrystal silicon substrate. Furthermore, correction etching mask 307 is formed, which is coupled with the projecting corner of the base etching mask 303 of the movable member. At the joint of the correction etching mask 307, a plurality of through-holes 351, which constitute the lowered-strength portion, are formed.

As depicted by a broken line in FIG. 3B, as a silicon substrate is soaked in the anisotropic wet etching solution, the etching progresses, and, at the protruded portion of the edge of the correction etching mask 307, the silicon underneath the mask is etched. As the etching progresses, the silicon substrate is etched as depicted by a broken line in FIG. 3C, and the silicon portion under the correction etching mask 307 is etched. Finally, as shown in FIG. 3D, the silicon portion under the base etching mask 303 of the movable member remains, and the final shape is provided. In the final shape, while all the silicon under the correction etching mask is etched, the side etching progresses. The protruded portion is slightly etched, and a side etched portion 311 as shown by a broken line in FIG. 3D is formed. Since the correction etching mask is coupled with the base etching mask, even if the final shape is made and the silicon below the correction etching mask is removed, one end of the correction etching mask is connected with the base etching mask.

Here, in the correction etching mask 307, the silicon under the through-hole 351 has been removed. Therefore, a perforated shape is formed where the through-hole 351 of the correction etching mask 307 is present, and a lowered-strength portion is formed at that location.

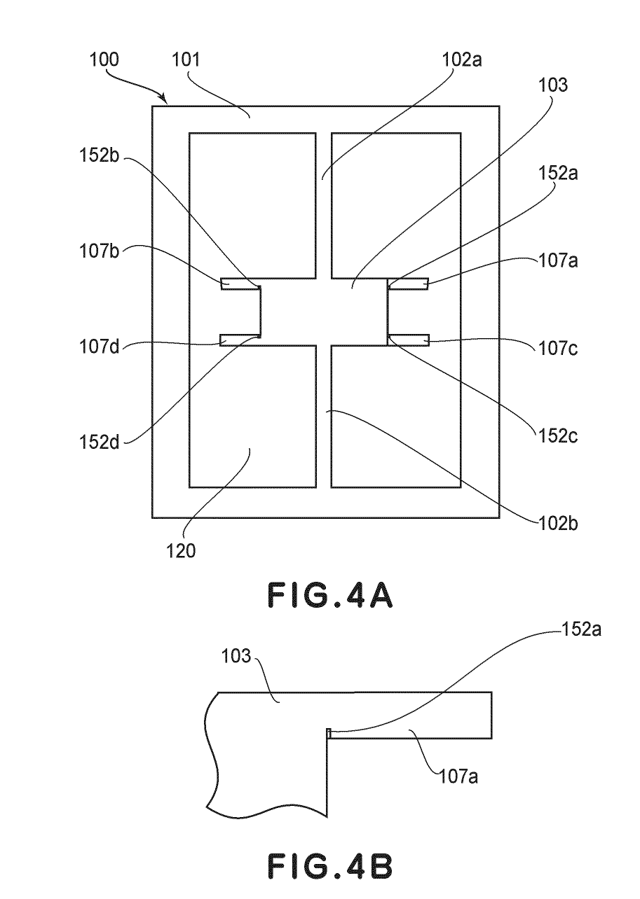

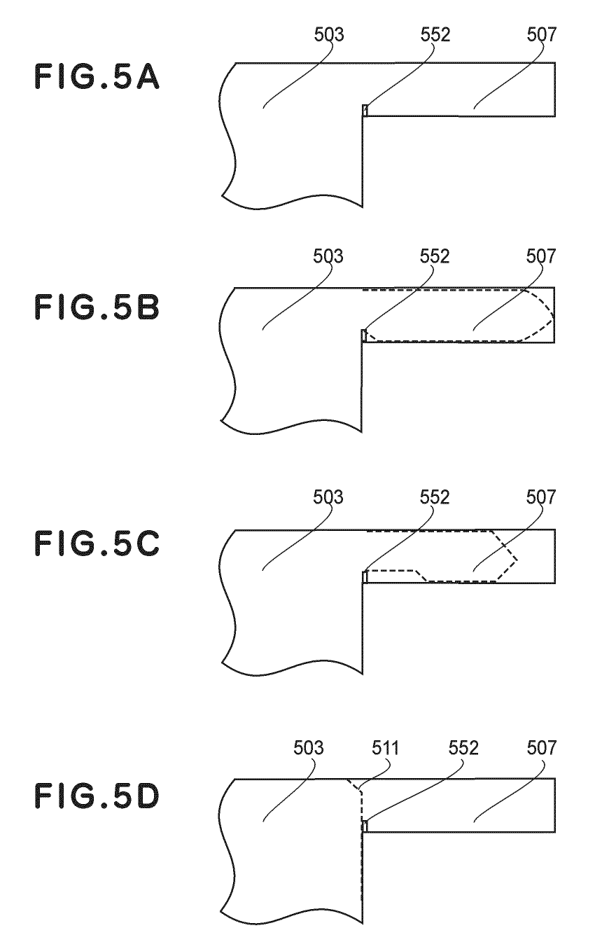

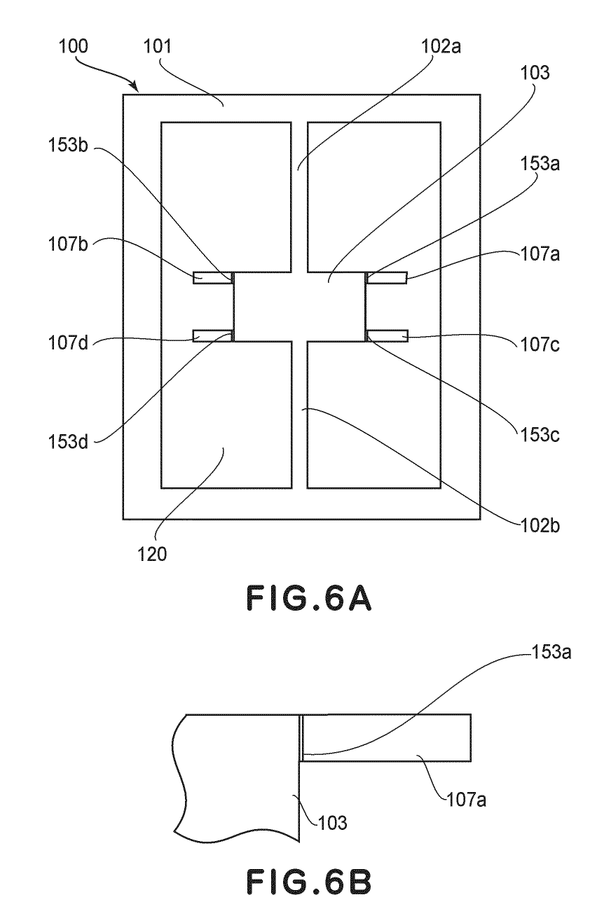

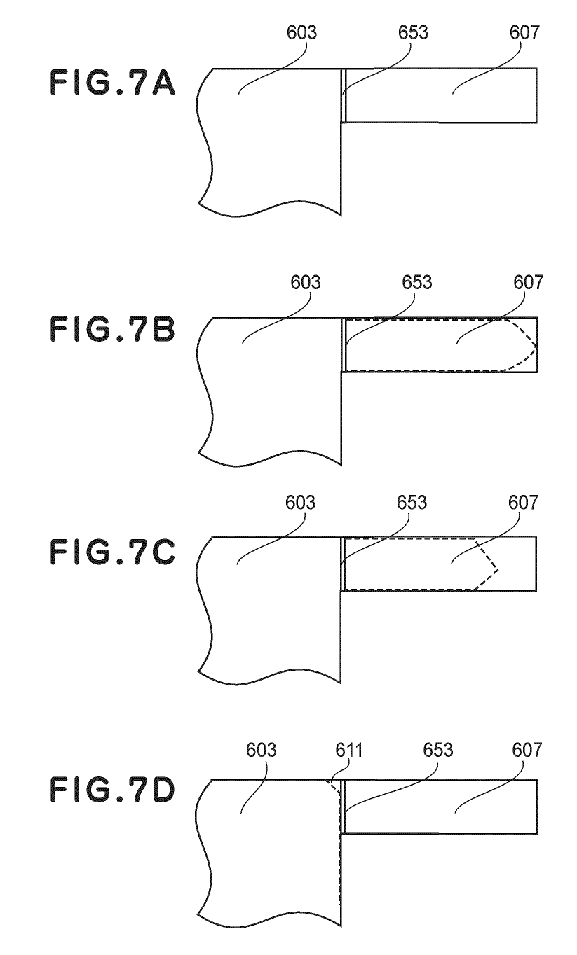

The structure of the lowered-strength portion is not limited to the form of through-holes in the mask material of the correction etching mask. Mask notches 152 and 552 of the correction etching mask, such as those shown in FIG. 4 and FIGS. 5A and 5B, or reduced-thickness portions 153 and 653 of the mask material of the correction etching mask, such as shown in FIG. 6 and FIGS. 7A and 7B, may be used. Alternatively, these forms may be used in combination.

FIGS. 4A, 4B, 5A, and 5B illustrate a modified form of the invention in which the lowered-strength portion is defined by one or more notches 152a-152d and 552. FIGS. 5A and 5B are enlarged views illustrating the etching process in a portion of the correction etching mask of FIG. 4B. The elements corresponding to those of FIG. 4B are denoted by numerals in the 500s.

As the silicon substrate 100 is dipped into the anisotropic wet etching solution, the etching advances as depicted by a broken line in FIGS. 5B and 5C leading to the final shape. In this case, in the final shape, the side etching progresses while all the silicon underneath the correction etching mask is etched. The protruded portion is slightly etched, and a side etched portion 511, as shown by a broken line in FIG. 5D, is formed.

FIGS. 6A, 6B, 7A, and 7B illustrate a modified form of the invention in which the lowered-strength portion is defined by one or more reduced-thickness portions 153a-153d and 653. FIGS. 7A and 7B are enlarged views illustrating the etching process in a portion of the correction etching mask of FIG. 6B. The elements corresponding to those of FIG. 6B are denoted by numerals in the 600s.

As the silicon substrate 100 is dipped into the anisotropic wet etching solution, the etching advances as depicted by a broken line in FIGS. 7B and 7C, and the final shape results. In this case, in the final shape, the side etching also progresses while all the silicon underneath the correction etching mask is etched. The protruded portion is slightly etched, and a side etched portion 611, as shown by a broken line in FIG. 7D, is formed.

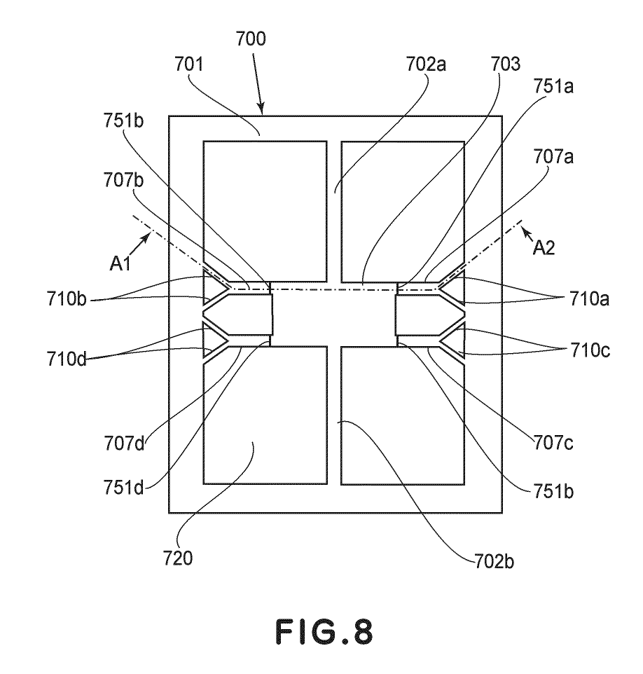

Next, the process of cutting the mask material of the correction etching mask at the joint having a lowered-strength portion in this embodiment of the present invention will be explained. Since the correction etching mask needs to be removed, it is necessary to perform such a step. As a matter of course, if in the final stage of the etching process the correction etching mask has already been separated at the lowered-strength portion, such a disconnecting step would not be necessary. With regard to the base etching mask, it may be left if it does not cause any inconvenience. Alternatively, it may be removed in an extra etching step if the removal is needed. The correction etching mask may be removed together at the removing step of the base etching mask. With regard to a correction etching mask in the form as shown in FIG. 8, which is described below, in some cases, the correction etching mask should be removed in an extra etching step together with the base etching mask.

One method of cutting the correction etching mask is oscillating the monocrystal silicon substrate within the anisotropic etching solution to cut the mask at the joint where a lowered-strength portion, which is weak in stress, is formed.

A second method is revolving the monocrystal silicon substrate within the anisotropic etching solution to cut the mask at the joint where a lowered-strength is formed.

A third method is applying a water shower against the monocrystal silicon substrate during the water rinsing of the silicon substrate so that the mask is cut at the joint where a lowered-strength portion is formed.

A fourth method is blowing air against the monocrystal silicon substrate during drying of the silicon substrate so that the mask is cut at the joint where a lowered-strength portion is formed.

A fifth method is subjecting the monocrystal silicon substrate within the anisotropic etching solution o or during rinsing of the silicon substrate to ultrasonic vibrations to cut the mask at the joint where a lowered-strength portion is formed.

Next, other embodiments of the present invention will be explained.

In another form, a base etching mask and a correction etching mask are made as follows. Here, a mask corresponding to the target shape (oscillator device) having at least a first structure (movable member) with a projecting corner and a second structure (supporting member) adjoining the first structure with an opening intervening therebetween, on a monocrystal silicon substrate, is taken as a base etching mask. Furthermore, a mask extending from the projecting corner of the etching mask of the first structure and coupled with an etching mask of the second structure is taken as a correction etching mask. In this embodiment, in the mask forming step, a lowered-strength portion, in which the mechanical strength is locally decreased, is formed at least in a portion of the joint where the correction etching mask couples with the base etching mask of the first structure. Furthermore, the correction etching mask may have a Y-letter shape, extending from the projecting corner of the etching mask of the first structure in the [110] directions and the correction etching masks branched off in the [100] directions are connected to the etching mask of the second structure.

A description is provided below with reference to the drawings.

The correction etching mask 707a, 707b, 707c, and 707d shown in FIG. 8 is connected to the protruding corner of the base etching mask 703 and extends in the [110] directions, which are the crystal orientation of silicon. Another end 710a, 710b, 710c, and 710d of the correction etching mask branches off in the [100] directions from the correction etching mask 707a, 707b, 707c, and 707d and is connected to the supporting member 701. The correction etching mask 707a, 707b, 707c, and 707d has a rectangular shape connected to the projecting corner of the base etching mask 703 of the movable member and extends in one direction. Also, the correction etching mask 707a, 707b, 707c, and 707d is connected to the correction etching mask 710a, 710b, 710c, and 710d, which has a rectangular shape extending in another direction. The correction etching mask 710a, 710b, 710c, and 710d is connected to the base etching mask 701 of the supporting member. Furthermore, there is at least one through-hole 751a, 752b, 753c, or 754d at the joint with the movable member of each part of the correction etching mask 707a, 707b, 707c, and 707d.

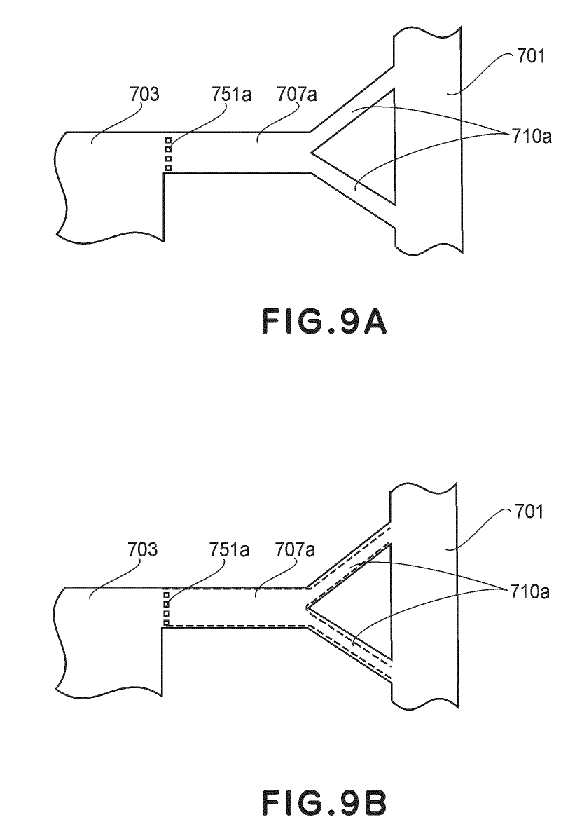

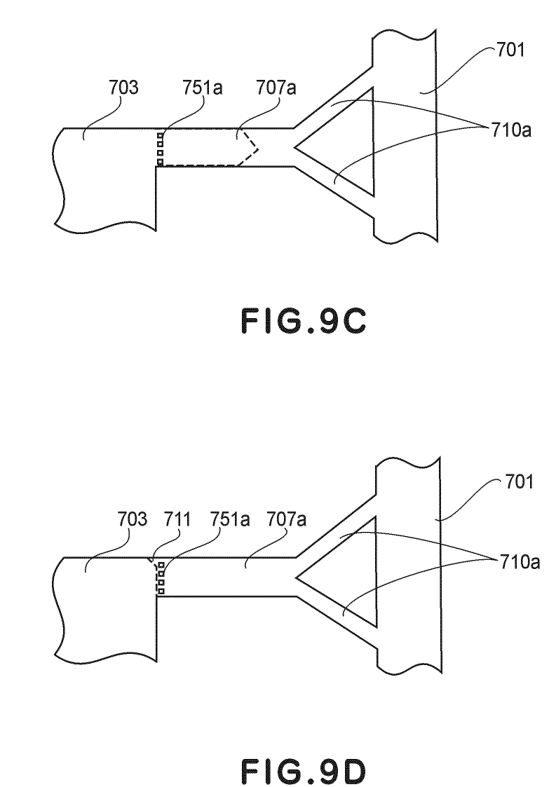

FIG. 9A and FIG. 9B are enlarged views of a portion of the correction etching mask of FIG. 8. In this embodiment of the present invention, as shown in FIG. 8, a base etching mask 703 of the movable member and a base etching mask 701 of the supporting member and a base etching mask 702a and 702b of the resilient supporting members are formed on a monocrystal silicon substrate 700. Furthermore, a correction etching mask is formed, which is coupled with the base etching mask 703 of the movable member and the base etching mask 701 of the supporting member.

As shown in FIG. 9B, as a silicon substrate 700 is soaked in the anisotropic wet etching solution, the etching progresses, and mainly the silicon underneath the correction etching mask 710a as well is etched. As the etching progresses further, the silicon substrate under the correction etching mask 710a is etched as shown in FIG. 9C, and the silicon portion under the correction etching mask 707a is etched. Finally, as shown in FIG. 9D, a silicon penetrated portion 720 is formed and the silicon portion under the base etching mask 703 of the movable member remains. Thus, the final shape is produced. In the final shape, while all the silicon under the correction etching mask is etched, the side etching progresses. The protruded portion is slightly etched, and a side etched portion 711 as shown by a broken line in FIG. 9D is formed. Since the correction etching mask is coupled with the base etching mask, even if the final shape is made and the silicon below the correction etching mask is removed, the opposite ends of the correction etching mask are connected with the base etching mask.

Here, in the correction etching mask 707a, the silicon under the through-hole 751a has been removed. Therefore, a perforation shape is formed at the place where the through-hole 751a of the correction etching mask 707a is present, and a lowered-strength portion is formed at that location. Here, the lowered-strength portion is similar to that of the correction etching mask of the FIG. 1 embodiment in which it is connected only to the movable member. Namely, the lowered-strength portion may be provided by not only a through-hole formed in the mask material of the correction etching mask, but also by a notch of the correction etching mask or a reduced-thickness portion of the correction etching mask. Alternatively, it may be provided by a combination of these features.

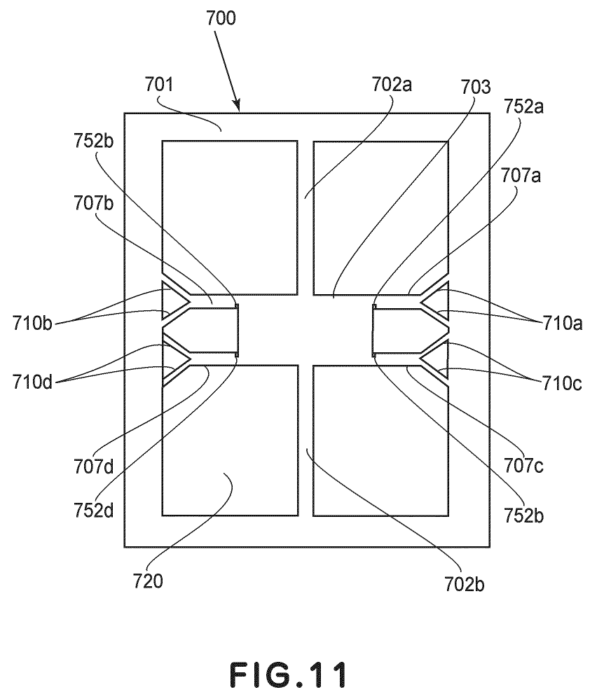

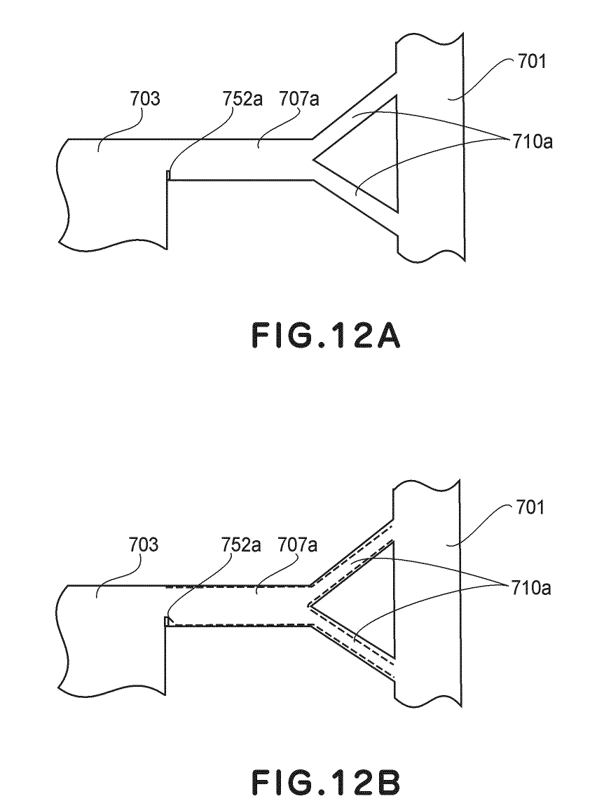

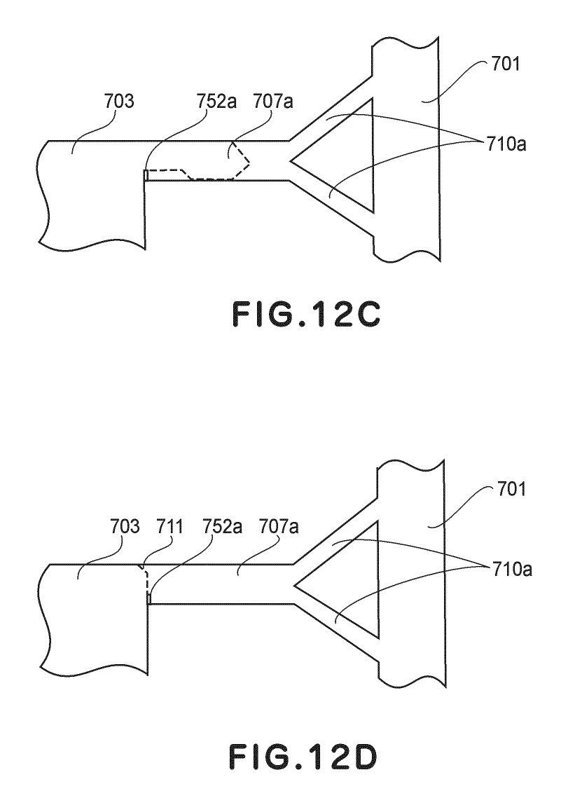

FIG. 11 and FIGS. 12A and 12B illustrate a modified form of the invention in which the lowered-strength portion is defined by at least one notch 752. FIGS. 12A and 12B are enlarged views illustrating the etching process in a portion of the correction etching mask of FIG. 11.

As the silicon substrate 700 is dipped into the anisotropic wet etching solution, the etching advances as depicted by a broken line in FIGS. 12A and 12B, and the final shape is produced. In this case, in the final shape, the side etching progresses while all the silicon underneath the correction etching mask is etched. The protruded portion is slightly etched, and a side etched portion 711 as shown by a broken line in FIG. 12D is formed.

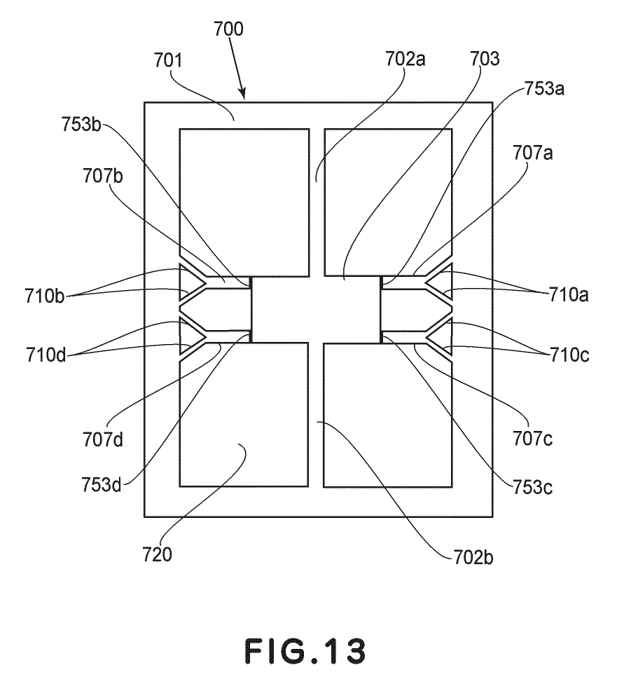

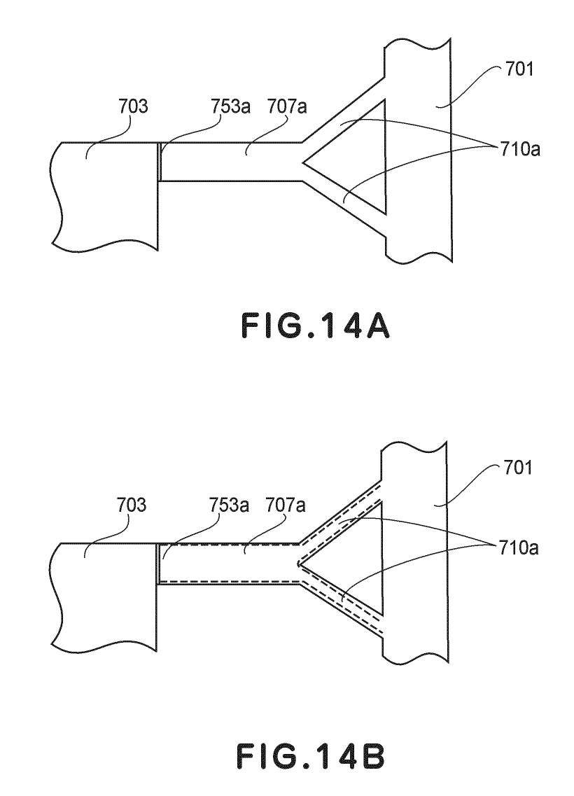

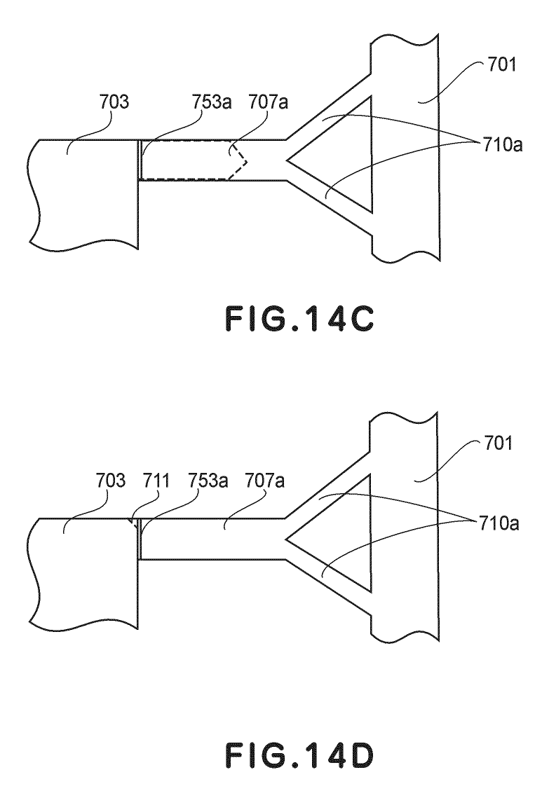

FIG. 13 and FIGS. 14A and 14B illustrate a modified form of the invention in which the lowered-strength portion is defined by at least one reduced-thickness portion 753. FIGS. 14A and 14B are enlarged views illustrating the etching process in a portion of the correction etching mask of FIG. 13.

As the silicon substrate 700 is dipped into the anisotropic wet etching solution, the etching advances as depicted by a broken line in FIGS. 14A and 14B, and the final shape is produced. In this case, in the final shape, the side etching progresses while all the silicon underneath the correction etching mask is etched. The protruded portion is slightly etched, and a side etched portion 711 as shown by a broken line in FIG. 14D is formed.

In this embodiment of the present invention, the process of cutting at the joint formed with a lowered-strength portion is also similar to the correction etching mask coupled only with the movable member. However, in this embodiment, there is a joint having no lowered-strength portion. The influence of this will be explained.

FIGS. 10A-10C are A1-A2 sectional views of FIG. 8. Here, a mask pattern is formed on both surfaces of the silicon substrate 700. FIG. 10A is a sectional view of the silicon substrate on which an etching mask is formed, and FIG. 10B is a sectional view of the silicon substrate 700 when the etching is finished. As shown in FIG. 10B, as the etching is completed, the silicon under the correction etching mask 707a, 707b, 707e, 707f, 710a, 710b, 710e, and 710f has been etched. In this way, the correction etching mask with lowered-strength portions 751a, 751b, 751e, and 751f is in state just like a single-side supported state. Thus, the correction etching mask can be very easily broken at the lowered-strength portion. Furthermore, the silicon underneath the correction etching mask has been removed and no silicon substrate is present at that location. Additionally, the thickness of the correction etching mask is very small, on a submicron order. Because of this, the correction etching mask can be very easily broken. Furthermore, since there is a residual stress in the mask material caused during the film formation, after the silicon substrate is etched, due to the stress, the correction etching mask can be very easily deformed. In FIGS. 10A-10C, base etching masks are denoted as 701a, 701b, 701e, 701f, 703a, and 703b on the top and bottom surfaces of the silicon substrate 700.

If, as shown in FIG. 10C, the correction etching mask is broken during the etching process and it sticks to a silicon portion to be etched, the adhered silicon will be removed due to the etching. If it is deposited on another etching mask, the mask thickness at the portion where the broken mask material is deposited will double. This makes it possible that, in the process of separating the etching mask, the mask material may be left at the large-thickness portion or it may becomes necessary to double the separating process time. If the separating time is lengthened, it is possible that the silicon portion may also be altered. Hence, there is a large possibility that the final shape differs from the target shape.

The structure manufacturing method in this embodiment of the present invention uses a correction etching mask, and a lowered-strength portion is formed beforehand in the mask material of the correction etching mask, which is very fragile. With this arrangement, in the process of forming a target shape based on the etching using an anisotropic etching solution, a disengagement or disconnection of the mask easily occurs at all the lowered-strength portions of the mask material of the correction etching mask. Since, however, the lowered-strength portion is formed at the joint with the base etching mask of the movable member, even if such mask disengagement or disconnection occurs, the correction etching mask does not easily stick to the movable member of the target shape. Thus, the possibility that the movable member, which should be precisely formed into a target shape, is influenced by the adhesion of the correction etching mask material when the mask disengagement or disconnection occurs is significantly reduced. FIG. 10C illustrates this point.

In this manner, the possibility of producing a shape different from the target shape where it is important to maintain strict geometrical accuracy is significantly reduced. Therefore, the deficient product ratio of the structure can also be reduced. In other words, in this embodiment of the present invention, the correction etching mask is provided with a lowered-strength portion so as to increase the possibility that, even if the correction etching mask is broken during the etching process, it has no adverse influence on the movable portion.

What is described above similarly applies to the correction etching mask connected only to the movable member and also to the correction etching mask connected to both of the movable member and the supporting member. Namely, once a lowered-strength portion is formed at the joint of the correction etching mask connecting to the base etching mask of the movable member, in both cases, the deficient product ratio can be reduced.

The structure in the embodiment described above may be such that a base etching mask and a correction etching mask are formed on both surfaces of a monocrystal silicon substrate, wherein, on each surface, the base etching mask and the correction etching mask have the same shape and are aligned with each other along a longitudinal direction. With this method, structures of the same shape can be formed on both surfaces of the substrate. In that case, although there are correction etching masks on both surfaces and thus the possibility that a correction etching mask may break increases to some extent, the deficient product ratio will be reduced as compared with conventional examples.

Furthermore, in accordance with the structure manufacturing method of the embodiment described above, an oscillator device having a supporting member, a movable member, a resilient supporting member for resiliently connecting the movable member to the supporting member for oscillation about the oscillation axis, and driving means for driving the movable member can be produced. In that case, a magnetic material 205 and an electric coil 206, such as shown in FIG. 2B, may constitute the driving means. Since the deficient product ratio of oscillator devices produced in accordance with this manufacturing method can be reduced, comparatively inexpensive oscillator devices can be provided.

Furthermore, an optical deflecting element may be mounted on a movable member unit of the oscillator to provide an optical deflector. In such an optical deflector, incident light is deflectively reflected by a reflection surface 204 as shown in FIG. 2B. Since the deficient product ratio of optical deflectors is reduced, inexpensive optical deflectors can be provided.

Furthermore, an optical instrument, such as an image forming apparatus in which a light source, an optical deflector as described above, and an object such as a photosensitive member to be irradiated are included and light from the light source, is deflected so that at least a portion of the light is incident on the object to be irradiated. Since an inexpensive optical deflector is used, a comparatively inexpensive optical instrument can be provided.

Furthermore, an embodiment of the present invention provides a photomask, that is, a tool made of fused quartz or the like used in a photolithographic process as a pre-process of the etching process based on the anisotropic etching for forming the correction etching mask of the present invention.

### WORKING EXAMPLES

Referring to the drawings, several working examples of the present invention will be explained.

### Working Example 1

Referring to FIGS. 1A, 1B, 2A, 2B, 3A, and 3B, the structure of an optical deflector, a driving method, and a manufacturing method thereof according to a first working example will be explained.

FIG. 1A is a top plan view of an etching mask of an optical deflector of the present embodiment, and FIG. 1B is an enlarged view of the correction etching mask of FIG. 1A, for explaining the etching mask of the present working example. FIGS. 2A and 2B are diagrams illustrating an optical deflector made by etching a monocrystal silicon substrate by the anisotropic etching.

As shown in FIGS. 2A and 2B, the optical deflector of this working example comprises a supporting member 201, a movable member 203, and resilient supporting members 202a and 202b. The resilient supporting members 202a and 202b function to resiliently connect the movable member 203 to the supporting member 201 for oscillation around the torsion axis 207. There is a reflection surface 204 formed on the movable member 203. In this working example, the material of reflection surface 204 is aluminum, and it is formed by vacuum deposition. However, the reflection surface 204 may be made of any other material, such as, for example, gold or copper. A protective film or a dielectric multilayer film may be formed thereon. As an example, the movable member 203 may have a length of 1.3 mm in the direction perpendicular to the torsion axis 207, a length of 1.5 mm in the direction parallel to the torsion axis 207, and a thickness of 0.2 mm. The full length of the optical deflector, for example, is 10 mm.

The driving principle of the optical deflector of this working example will be explained. As shown in FIG. 2B, the movable member 203 comprises a hard magnetic material 205. This material is magnetized in a direction perpendicular to the torsion axis. The electric current to be applied to the electric coil 206 is an alternating current, and a magnetic field corresponding to the frequency of the alternating current is produced. This magnetic field applies a force to the hard magnetic material 205 of the movable member 203. In this manner, a torque is applied to the movable member 203, and the optical deflector is driven with torsional oscillation. Furthermore, by applying, to the electric coil 206, an alternating current that is the same as the resonance frequency of the optical deflector of this working example, torsional oscillation can be produced by slow power consumption.

The manufacturing method of the present working example will be explained with reference to FIGS. 1A and 1B. A silicon nitride film is layered on both surfaces of a monocrystal silicon substrate 100, with a thickness of about 2000 angstroms in accordance with an LPCVD (Low Pressure CVD) method. Since the silicon nitride film has a high resistance to a potassium hydroxide solution, it is not removed while the silicon substrate 100 is etched by the anisotropic etching solution. Subsequently, both surfaces of the monocrystal silicon substrate 100 are patterned by photolithography so that an etching mask pattern shown in FIG. 1 is provided. Afterwards, by using a potassium hydroxide solution (30% weight density), which is the anisotropic etching solution, heated to 110 degrees Celsius, the patterned silicon monocrystal substrate 100 is etched. After the etching is completed, the silicon nitride film, which is the etching mask, is separated by dry etching. Finally, aluminum, which provides a reflection surface 204, is layered, whereby a final shape, such as shown in FIG. 2A, is formed.

In the structure manufacturing method of this working example, the correction etching mask 107a, 107b, 107c, and 107d is connected to a projecting corner of the movable member 103, which is the base etching mask. There is at least one through-hole 151a, 152b, 153c, or 154d at the joint of each correction etching mask with the movable member 103.

The etching process of the present working example is such as the one described in the foregoing embodiment with reference to FIGS. 3A and 3B. As described above, since the correction etching mask is coupled with the base etching mask, even if the final shape is made and the silicon underneath the correction etching mask is removed, one end of the correction etching mask is connected to the base etching mask. Here, in the correction etching mask 307, there is a perforation shape at the place where the through-hole 351 is formed. Thus, a lowered-strength portion is formed. There are several methods for cutting the mask material of this correction etching mask at the lowered-strength portion, as described above. Another method is that, after the final shape is formed, the silicon nitride, film which is an etching mask including a correction etching mask, is separated by dry etching.

Conventionally, there is a possibility that a correction etching mask is damaged in the course of the etching process and if it sticks to the resilient supporting member 202a and 202b, for example, the shape of the resilient supporting member changes and the resilient supporting member becomes quite fragile. Furthermore, if it sticks to the movable member 203, a surface step will be formed on the reflection surface, causing degradation of the optical property of the optical deflector.

In accordance with the structure manufacturing method of the present working example, a lowered-strength portion is formed beforehand in the mask material of the correction etching mask, which is very fragile. With this arrangement, in the etching process based on the anisotropic etching solution for making a target shape, a disconnection or separation of the mask can very easily occur at all the lowered-strength portions of the mask material of the correction etching mask. Therefore, the correction etching mask does not easily stick to the movable member of the target shape, and the deficient product ratio of the structure where the shape differs from the target shape can be reduced.

### Working Example 2

Referring to FIGS. 8, 2A, 2B, 9A and 9B, a structure manufacturing method of the second working example will be explained. FIG. 8 is a top plan view illustrating the etching mask of the optical deflector of the present working example, and FIGS. 9A and 9B are enlarged views of the correction etching mask of FIG. 8 for explaining an etching mask of the present working example. The structure and the driving method of the optical deflector of the second working example are approximately the same as those of the optical deflector of the first working example.

In the manufacturing method of the present working example, a silicon nitride film is layered on both surfaces of the monocrystal silicon substrate 700 to a thickness of about 2000 angstroms in accordance with the LPCVD method. Since the silicon nitride film has a high resistance to a potassium hydroxide solution, it is not removed while the silicon substrate 100 is etched by the anisotropic etching solution. Subsequently, both surfaces of the monocrystal silicon substrate are patterned by photolithography so that an etching mask pattern shown in FIG. 8 is provided. Afterwards, by using potassium hydroxide solution (30% weight density), which is the anisotropic etching solution, heated to 110 degrees Celsius, the patterned silicon monocrystal substrate is etched. After the etching is completed, the silicon nitride film, which is the etching mask, is separated by dry etching. Finally, aluminum, which provides a reflection surface 204, is layered, whereby a final shape, such as shown in FIG. 2A, is formed.

In the structure manufacturing method of this working example, the correction etching mask 707a, 707b, 707c, and 707d is connected to a projecting corner of the base etching mask 703 as shown in FIG. 8. The other end 710a, 710b, 710c, and 710d of the correction etching mask is connected to the supporting member 701. The correction etching mask 707a, 707b, 707c, and 707d has a rectangular shape connected to the protruding corner of the base etching mask 703 of the movable member and extending in one direction. The correction etching mask 707a, 707b, 707c, and 707d is also connected to the correction etching mask 710a, 710b, 710c, and 710d having a rectangular shape extending in a different direction. The forked correction etching mask 710a, 710b, 710c, and 710d is connected to the base etching mask of the supporting member. Furthermore, there is at least one through-hole 751a, 752b, 753c, or 754d at the joint with the movable member of each of the correction etching masks 703.

The etching process of the present working example is such as the one described in the foregoing embodiment with reference to FIGS. 9A and 9B. As described above, since the correction etching mask is coupled at all of its end portions with the base etching mask, even if the final shape is made and the silicon underneath the correction etching mask is removed, the end of the correction etching mask is connected to the base etching mask. Here, in the correction etching mask, since the silicon underneath the through-hole has been removed, there is a perforated shape at the place where the through-hole 351 is formed. Thus, a lowered-strength portion is formed. The cutting method is similar to the case where the correction etching mask is connected only to the movable member. There are several methods for disconnecting the mask material of the correction etching mask at its lowered-strength portion, as described hereinbefore. However, since in this working example the correction etching mask is connected to the base etching mask even at the end portion having no lowered-strength portion, in some cases, the removal by cutting will not be easy. However, even if the etching mask cannot be removed entirely, after the final shape is formed, the silicon nitride film, which is an etching mask including the correction etching mask, may be separated by dry etching, using which all can be removed. For easy separation, all the joints of the correction etching mask may be provided with lowered-strength portions, such as through-holes.

The advantageous effect of the manufacturing method according to the structure of the present working example is approximately the same as the effect of the working example described with reference to FIG. 10. In the present working example, the correction etching mask also does not easily stick to the movable member of the target shape, and the deficient product ratio in which the shape different from the target shape is formed is significantly reduced.

### Working Example 3

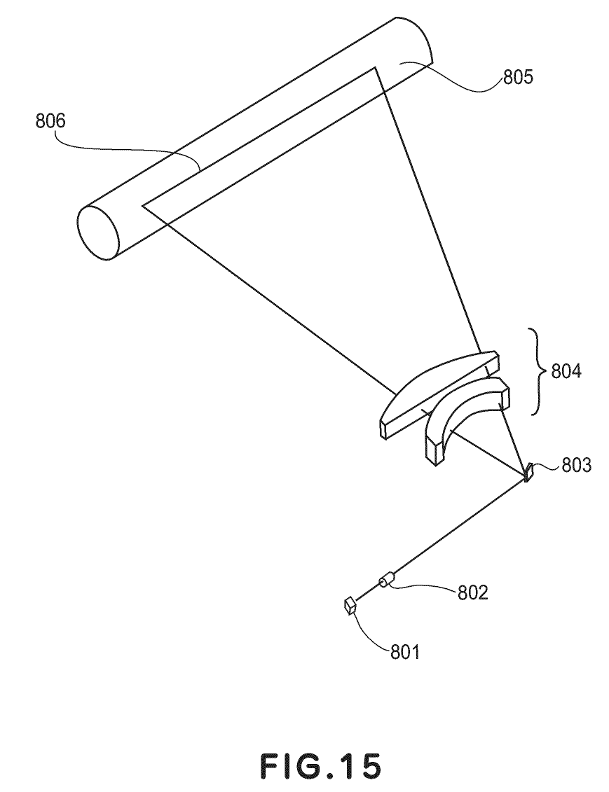

FIG. 15 is a diagram for explaining a working example of an optical instrument using an optical deflector described above. Here, an image forming apparatus is shown as an optical instrument. In FIG. 15, denoted at 803 is an optical deflector of the present invention. In this working example, it one-dimensionally scans the incident light. Denoted as 801 is a laser source. Denoted as 802 is a lens or lens group, and denoted as 804 is a writing lens or lens group. Denoted as 805 is a photosensitive member of drum shape. Denoted as 806 is the locus of the scan.

Light from the light source is intensity-modulated in relation to the timing of the deflective scan of the light, and the light is scanned one-dimensionally by the optical deflector 803. Then, through the writing lens 804, the scanning laser beam forms an image upon the photosensitive member 805. The photosensitive member 805 is being uniformly charged by a charging device (not shown). When the photosensitive member surface is scanned with light, an electrostatic latent image is formed on the portion scanned by the light.

Subsequently, a toner image is formed on the imagewise portion of the electrostatic latent image by means of a developing device (not shown). The toner image is then transferred to and fixed on a paper sheet (not shown), whereby an image is produced on the paper sheet.

Here, since the image forming apparatus uses an optical deflector of the present invention, which can be manufactured with a decreased deficient product ratio, the image forming apparatus can be provided relatively inexpensively.

The optical deflector of the present invention can be applied to any other optical instruments. In these devices, it can operate to deflect a light beam from a slight source and to make at least a portion of the light beam incident on a member to be irradiated. Example of such optical instruments are an image forming apparatus, such as a laser beam printer and an image display unit, and a mechanical device, such as a bar code reader, in which the light beam should be scanned.

While the invention has been described with reference to the structures disclosed herein, it is not confined to the details set forth, and this application is intended to cover such modifications or changes as may come within the purposes of the improvements or the scope of the following claims.

This application claims priority from Japanese Patent Application No. 2007-327510, filed Dec. 19, 2007, which is hereby incorporated herein by reference.

What is claimed is:

1. A method of manufacturing a structure, comprising:
a mask forming step for forming, on a monocrystal silicon substrate, a base etching mask corresponding to a target shape and a correction etching mask having a joint connecting to the base etching mask; and
a target shape forming step for forming the target shape by etching the silicon substrate based on anisotropic etching;
wherein, in said mask forming step, a lowered-strength portion where a mechanical strength is locally lowered is formed at least in a portion of the joint of the correction etching mask.

2. A method of manufacturing a structure, comprising:
a mask forming step for forming, on a monocrystal silicon substrate, a base etching mask corresponding to a target shape having at least a first structure with a projected corner and a second structure adjoining the first structure with an opening interposed therebetween, and a correction etching mask extending from the projected corner of the etching mask of the first structure and connecting to the etching mask of the second structure; and
a target shape forming step for forming the target shape by making anisotropic etching of the silicon substrate having the basic etching mask and the correction etching mask;
wherein, in said mask forming step, a lowered-strength portion where a mechanical strength is locally lowered is formed at least in a portion of a joint where the basic etching mask of the first structure connects with the correction etching mask.

3. A method according to claim 2, wherein the correction etching mask has a Y-shape form in which it extends from the projected corner of the etching mask of the first structure in [110] directions and in which respective correction etching masks branched in the [100] directions connect with the etching mask of the second structure.

4. A method according to claim 2, wherein said target shape forming step includes a step of removing the silicon substrate in a portion where the correction etching mask is formed.

5. A method according to claim 2, further comprising a disconnecting step for cutting the correction etching mask at the joint in which the lowered-strength portion is formed.

6. A method according to claim 2, wherein the lowered-strength portion is provided by at least one of (i) one or more through-holes, (ii) one or more slits and (iii) one or more thin-thickness portions.

7. A method according to claim 5, wherein, in said disconnecting step, the correction etching mask is cut at the joint where the lowered-strength portion is formed, the cutting being made based on at least one of (i) making oscillatory motion of the silicon substrate in an anisotropic etching solution for the anisotropic etching, (ii) making revolving motion of the silicon substrate in an anisotropic etching solution for the anisotropic etching, (iii) applying water shower to the silicon substrate during water rinsing of the silicon substrate, (iv) blowing an air against the silicon substrate during drying of the silicon substrate, and (v) applying ultrasonic vibration to the silicon substrate in an anisotropic etching solution for the anisotropic etching or during water rinsing of the silicon substrate.

8. A silicon substrate with an etching mask, comprising:
a monocrystal silicon substrate;
a base etching mask corresponding to a target shape and formed on the monocrystal silicon substrate;
a correction etching mask having a joint connecting to the base etching mask and formed on the monocrystal silicon substrate;
a lowered-strength portion having a locally lowered mechanical strength and formed at least in a portion of the joint of the correction etching mask.

9. An oscillator device, comprising:
a supporting member;
a movable member being movably supported relative to said supporting member;
a resilient supporting member for resiliently connecting said movable member to said supporting member for oscillatory motion around an oscillation axis; and
a driving member for driving said movable member,
wherein said oscillator device is manufactured in accordance with the manufacturing method as recited in claim 2.

10. An optical deflector, comprising:
an oscillator device as recited in claim 9; and
an optical deflecting element provided on the movable member.

11. An optical instrument, comprising:
an optical deflector as recited in claim 10;
wherein said optical deflector is configured to deflect a light beam from a light source, such that at least a portion of the light beam is incident on an object to be irradiated thereby.
